(19) United States
(12) Patent Application Publication
(10) Pub. No.: US 2016/0097958 A1
(43) Pub. Date: Apr. 7, 2016

(54) LIQUID CRYSTAL DISPLAY PREVENTED FROM LIGHT LEAKAGE, AND METHOD OF FABRICATING THE SAME

(71) Applicant: Samsung Display Co., Ltd., Yongin City (KR)

(72) Inventors: Seung Kyu LEE, Yongin-City (KR); Youn Hak JEONG, Yongin-City (KR); Hong Min YOON, Yongin-City (KR); Gung Wan NAM, Yongin-City (KR); Ho Jun LEE, Yongin-City (KR)

(21) Appl. No.: 14/875,408

(22) Filed: Oct. 5, 2015

(30) Foreign Application Priority Data
Oct. 7, 2014 (KR) 10-2014-0135180

(51) Int. Cl. G02F 1/1362; H01L 27/12; G02F 1/1368

(52) U.S. Cl. CPC G02F 1/136286; G02F 1/1368; H01L 27/1262; G02F 2001/136218; G02F 2001/136295

(57) ABSTRACT

Disclosed are a liquid crystal display in which a light leakage phenomenon is prevented, and a method of fabricating the same. The liquid crystal display includes: an array substrate; and an opposite substrate facing to the array substrate; and a liquid crystal layer between the array substrate and the opposite substrate. The array substrate includes a first base substrate in which pixel areas are defined, and the first base substrate includes a gate line, a data line crossing the gate line and voltage application lines having two lines disposed at both sides of the gate line and two lines disposed at both sides of the data line, a switching element connected with the gate line and the data line in the pixel area, and a shielding electrode and a pixel electrode on the data line. The data line and the two lines disposed at both sides of the data line at least partially overlap. Therefore, it is possible to fundamentally block light emitted from a lower backlight even without a black matrix, thereby preventing light leakage and improving transmissivity.

### CROSS-REFERENCE TO RELATED APPLICATION

This application claims priority to and the benefit of Korean Patent Application No. 10-2014-0135180, filed on Oct. 7, 2014, in the Korean Intellectual Property Office, the entire contents of which are incorporated herein by reference in their entirety.

### BACKGROUND

1. Field

The present application relates to a liquid crystal display, in which light leakage is prevented, and a method of fabricating the same, and more particularly, to a liquid crystal display which is capable of fundamentally blocking light emitted from a lower backlight through a structure in which a data line overlaps a gate line.

2. Description of the Related Art

A Liquid Crystal Display (LCD) displays an image by applying a voltage to a liquid crystal layer interposed between two substrates and controlling transmissivity of light.

Recently, remarkable development of the LCD has been applied to a technical field related to a television (TV), and thus, various types of TVs, such as a 3D TV, an Organic Light Emitting Diode (OLED) TV, an ultra HD TV, a curved TV, and a variable curved TV, have appeared.

Among them, the curved TV has advantages described below. In terms of a flat panel TV, distances from a center of a screen to areas around edges of the screen are not equal to each other, so that there is a case where the screen is distortedly viewed or recognition of corner parts deteriorates. However, in terms of the curved TV, view distances are the same in all of the parts of a screen, so that it is possible to minimize screen distortion and deterioration of screen recognition.

However, an LCD applied to the curved TV has a problem in that a panel is bent and thus, the liquid crystal layer is distorted by a step, thereby degrading transmissivity.

Since the LCD allows light to pass only in a direction in which the LCD is not shielded by liquid crystal molecules of the liquid crystal layer to implement an image, the LCD has a relatively small viewing angle compared to other display devices. Accordingly, in order to implement a wide viewing angle, an LCD display having a Vertically Aligned (VA) structure has been developed.

The LCD having the VA structure includes a liquid crystal layer having negative type dielectric constant anisotropy, which is sealed between two vertically aligned substrates. Liquid crystal molecules of the liquid crystal layer have a homoetropic alignment property. When a voltage is not applied between the two substrates during an operation of the LCD, the liquid crystal layer is aligned in an appropriately vertical direction with respect to a surface of the substrate to display black. When a predetermined voltage is applied between the two substrates, the liquid crystal layer is aligned in an appropriately horizontal direction with respect to the surface of the substrate to display white. When a voltage smaller than a voltage for displaying white is applied, the liquid crystal layer is aligned to be inclined with respect to the surface of the substrate to display gray.

The LCD has a disadvantage in that a viewing angle is small. In order to solve the disadvantage, a Patterned Vertical Alignment (PVA) structure and a Super Patterned Vertical Alignment (SPVA) structure, in which one pixel is divided into multiple domains to be driven, have been developed. The PVA structure is a technique for patterning a common electrode and a pixel electrode formed on an upper substrate and a lower substrate to implement multiple domains. The SPVA is a technique, which is developed one stage from the PVA, for dividing one pixel into a plurality of sub pixels, and applying different voltages to the sub pixels.

An example of the SPVA structure includes a Coupling Capacitor (CC)-SPVA structure in which different pixel voltages are applied to the sub pixels by using a coupling capacitor.

As illustrated in FIG. 2, the SPVA structure in the related art, which is one structure of a panel PVA structure, is a structure in which an organic layer 16 is deposited between a data line 15 and a pixel electrode 18 on a lower substrate 10, and a color filter 22 of RGB is deposited on an upper substrate 20. A horizontal black matrix is applied to an area of a gate line and a vertical black matrix is applied to an area of a data line to attempt to prevent light leakage.

The SPVA structure in the related art may use a method of controlling light leakage by using a black matrix BM and a shielding electrode 17, but light leakage may be generated due to an increase in a voltage difference value A between a voltage of the shielding electrode 17 and a voltage of the common electrode 24, or a factor, such as an impact and mis-alignment, and further a lateral surface is weak to light leakage, so that the SPVA structure in the related art has a lot of structural problems.

As illustrated in FIG. 1 and FIG. 2, in the SPVA structure in the related art, there is a space between the data line 15 and voltage application lines 12, so that the black matrix BM is disposed on the upper substrate in order to prevent light leakage generated through an empty space. The shielding electrode 17 cannot help but being widely disposed (being wide) due to a possibility in light leakage by a field between the common electrode 24 of the upper substrate and the data line 15.

### SUMMARY

Embodiments provide a liquid crystal display, which is capable of fundamentally blocking light emitted from a lower backlight, thereby preventing light leakage and improving transmissivity.

Embodiments also provide a method of fabricating a liquid crystal display, which is capable of fundamentally blocking light emitted from a lower backlight, thereby preventing light leakage and improving transmissivity.

An exemplary embodiment provides a liquid crystal display, in which a light leakage phenomenon is prevented, including: an array substrate; and an opposite substrate facing to the array substrate; and a liquid crystal layer between the array substrate and the opposite substrate. The array substrate includes a first base substrate in which pixel areas are defined, and the first base substrate includes a gate line, a data line crossing the gate line, voltage application lines having two lines disposed at both sides of the data line and parallel to the data line, a switching element connected with the gate line and the data line in the pixel area, and a shielding electrode and a pixel electrode on the data line. The data line and the two lines disposed at both sides of the data line at least partially overlap.

A width of the shielding electrode positioned on the data line and the voltage application lines may be smaller than a width of the data line according to overlapping of the data line and the voltage application lines. p The liquid crystal display may further include a gate insulating layer between the gate line and the data line.

The liquid crystal display may further include an organic layer between the data line and the shielding electrode.

The opposite substrate may not include a vertical black matrix in an area of the data line.

The liquid crystal display may have a Super Patterned Vertical Alignment (SPVA) structure or a Super Vertical Alignment (SVA) structure.

Another exemplary embodiment provides a method of fabricating a liquid crystal display, including: forming an array substrate including a first base substrate and a plurality of pixels included on the first base substrate; forming an opposite substrate including a common electrode provided on a second base substrate; and forming a liquid crystal layer between the array substrate and the opposite substrate. The forming of the array substrate includes forming a gate line and voltage application lines, forming a data line crossing the gate line on the first base substrate, forming a switching element connected with the gate line and the data line in a pixel area, and forming a shielding electrode and a pixel electrode on the data line. The voltage application lines have two lines disposed at both sides of the data line and parallel to the data line, the data line and the two lines disposed at both sides of the data line at least partially overlap.

According to the exemplary embodiment, in the liquid crystal display, light emitted from a lower backlight is fundamentally blocked by preferentially making the gate line and the data line partially overlap, thereby preventing light leakage.

Further, when such a structure is applied, it is possible to decrease a width of the shielding electrode, so that the pixel electrode may be further moved toward an inner side, and a non-transmissive part is decreased compared to the related art, so that it is advantageous in terms of transmissivity.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a top plan view of a liquid crystal display having a general SPVA mode.

FIG. 2 is a cross-sectional view of a liquid crystal display of FIG. 1 in the related art taken in a direction of an arrow A-A′ of FIG. 1.

FIG. 3 is a cross-sectional view of a liquid crystal display of FIG. 1 according to an exemplary embodiment taken in a direction of an arrow A-A′ of FIG. 1.

FIGS. 4A, 4B, 4C, 4D, 4E are process diagrams illustrating a fabricating process of the liquid crystal display according to an exemplary embodiment.

FIG. 5 is a cross-sectional view of an array substrate, an opposite substrate, and a liquid crystal layer in a liquid crystal display according to another exemplary embodiment.

FIG. 6 is a diagram illustrating a result of comparison of cross-sections and light leakage between the liquid crystal display in the related art and the liquid crystal display according to an embodiment.

### DETAILED DESCRIPTION

Hereinafter, exemplary embodiments will be described in detail with reference to the accompanying drawings.

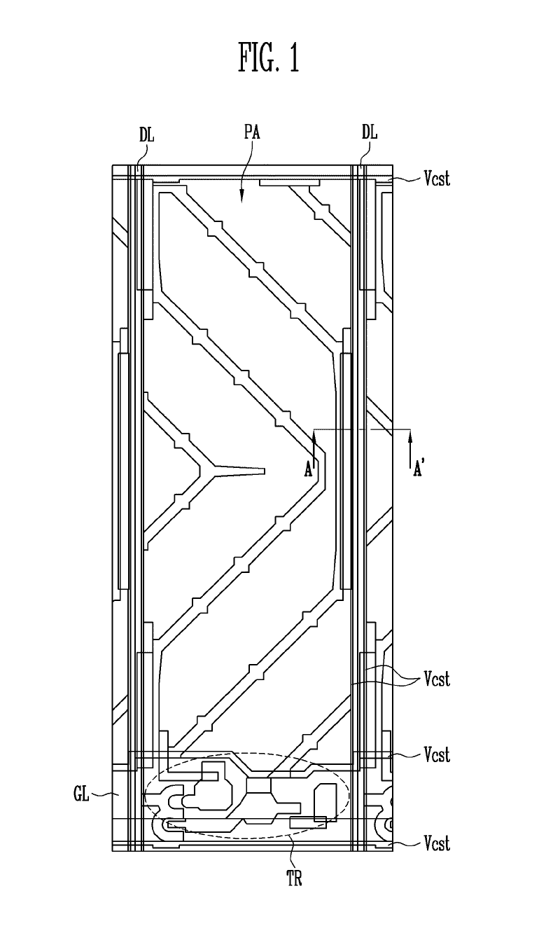

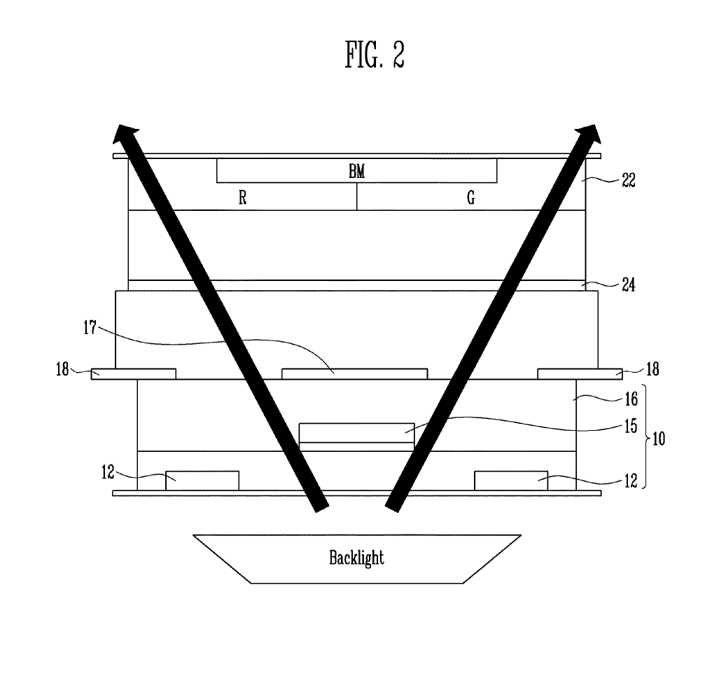

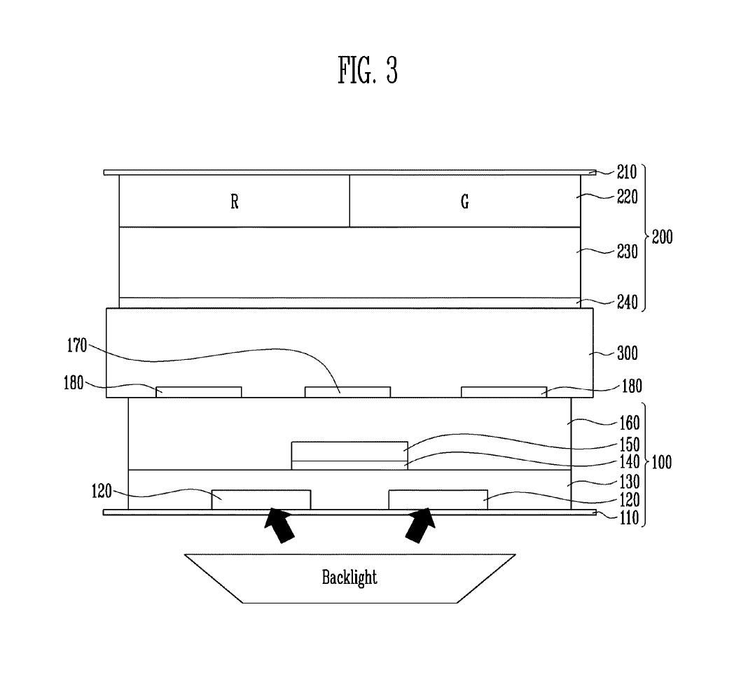

FIG. 1 is a top plan view of a liquid crystal display having a general SPVA mode. FIG. 2 is a cross-sectional view of the liquid crystal display of FIG. 1 having an existing SPVA mode taken in a direction of an arrow A-A′ in FIG. 1. FIG. 3 is a cross-sectional view of the liquid crystal display of FIG. 1 having an SPVA mode taken in a direction of an arrow A-A′ in FIG. 1 according to an exemplary embodiment.

Referring to FIGS. 1 and 3, a liquid crystal display according to an exemplary embodiment includes an array substrate 100, an opposite substrate 200, and a liquid crystal layer 300.

The array substrate 100 is an element substrate driven by an active matrix driving method using a thin film transistor (TFT element).

The opposite substrate 200 may be a color filter substrate including R, G, and B color filters.

Further, the array substrate 100 in the liquid crystal display includes a pixel electrode 180, and the opposite substrate 200 includes a common electrode 240.

The array substrate 100 may have an approximately quadrangular shape. Accordingly, a horizontal direction of the array substrate 100 is defined as an x direction, and a vertical direction of the array substrate 100 is defined as a y direction.

The array substrate 100 includes a first base substrate 110, gate lines GL including a gate electrode, voltage application lines 120, a gate insulating layer 130, an active pattern 140, data lines DL and 150 including source and drain electrodes, an organic layer 160, a shielding electrode 170, the pixel electrode PE and 180, and the like.

The gate lines GL may be extended in the horizontal (x) direction on the first base substrate 110. The gate lines GL may be arranged in the vertical (y) direction, which is different from the horizontal (x) direction, in parallel. The vertical direction (y) may be, for example, a direction vertical to the horizontal direction (x).

The voltage application lines 120 may be disposed on the same layer as the gate lines GL. The voltage application lines 120 may comprise two lines disposed between the gate lines GL adjacent to each other and parallel to the gate lines GL, and two lines disposed between the data lines DL and 150 adjacent to each other. That is, the voltage application lines 120 may comprise two lines disposed at both sides of the gate line GL and two lines disposed at both sides of the data line DL and 150. The two lines disposed at both sides of the gate line GL may be parallel to the gate line GL, and the two lines disposed at both sides of the data line DL and 150 may be parallel to the data line DL and 150.

The gate insulating layer 130 is formed on the first base substrate 110 so as to cover the gate lines GL and the voltage application lines 120. The data lines DL and 150 may be extended in the vertical (y) direction on the gate insulating layer 130, and arranged in parallel in the horizontal (x) direction. The data lines DL and 150 cross the gate lines 120, respectively. In the array substrate 100, pixel areas PA are divided by the gate lines 120 and the data lines DL and 150, and the pixel electrode 180 may be formed on the pixel area PA.

A switching element TR may include a gate electrode connected with the gate line 120, a semiconductor layer formed on the gate insulating layer 130 so as to correspond to the gate electrode, a source electrode connected with the data line DL and 150 and overlapping the active pattern 140, and a drain electrode spaced apart from the source electrode and overlapping the active pattern 140. The semiconductor layer may be disposed on the same layer as the active pattern 140. An ohmic contact layer may be disposed between the data line DL and 150 and the active pattern 140, and between the source and drain electrode and the semiconductor layer.

The organic layer 160 may be formed on the gate insulating layer 130 so as to cover the data lines DL and 150, and the source and drain electrodes.

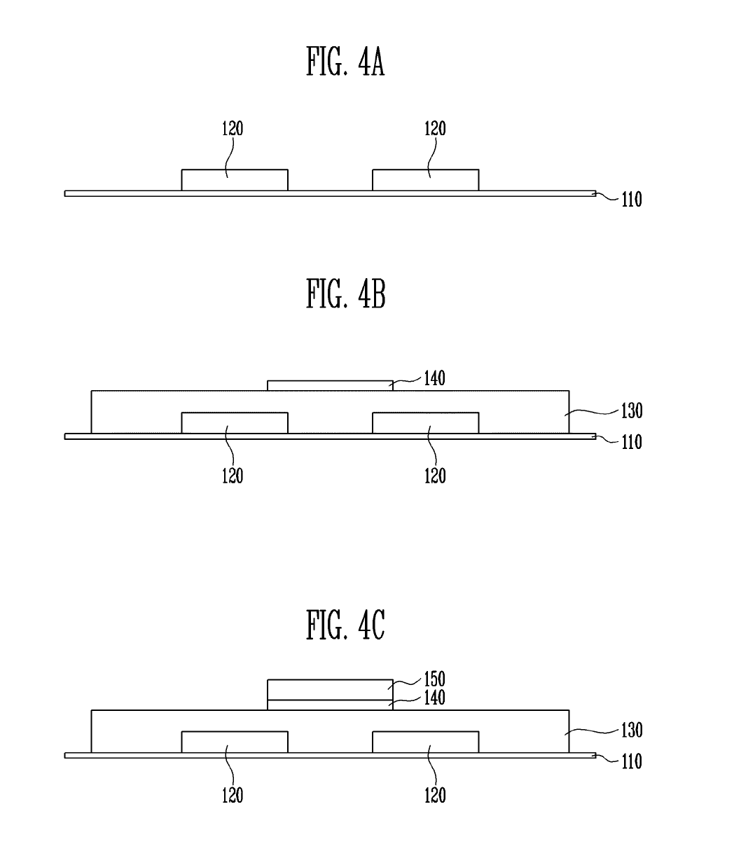

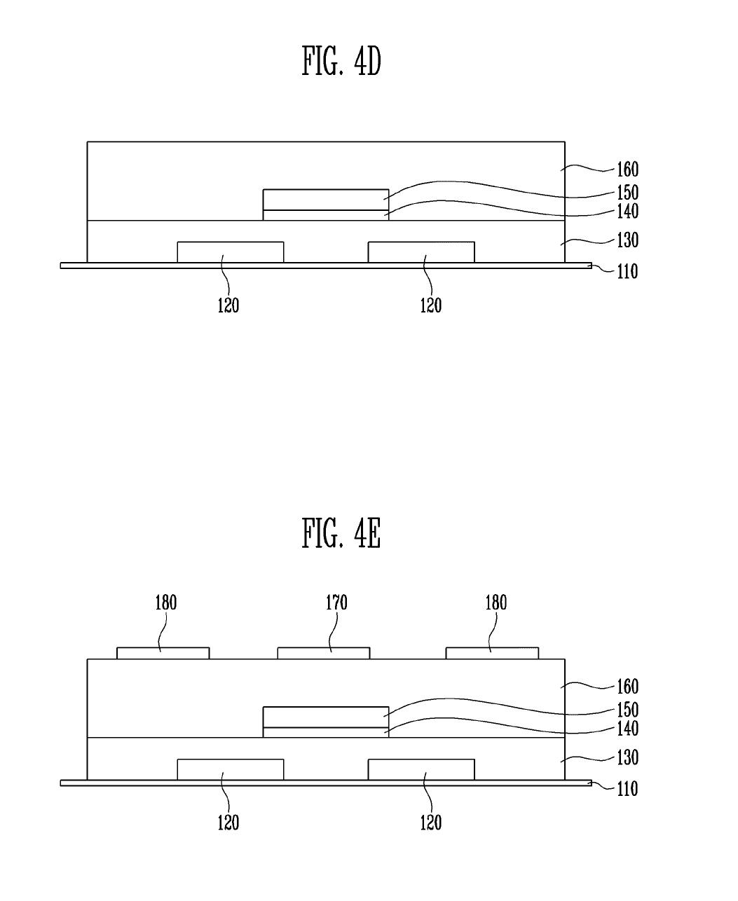

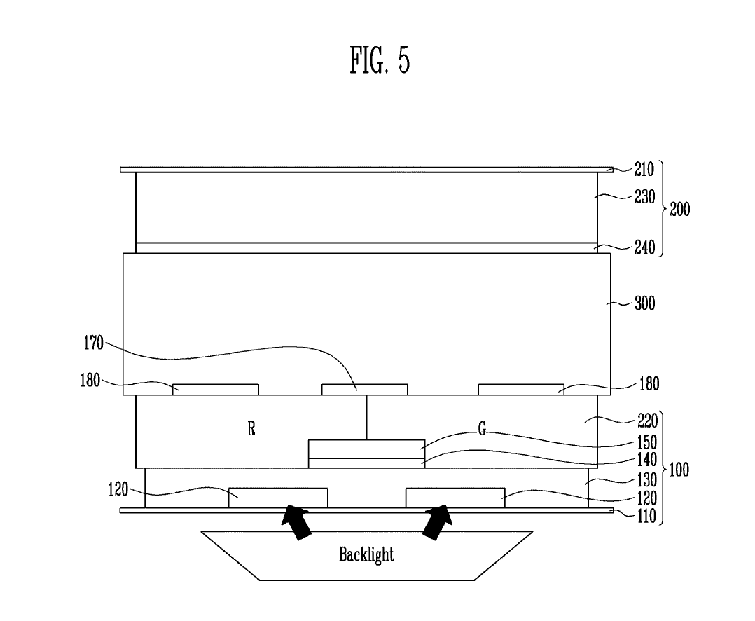

FIGS. 4A to 4E are process diagrams illustrating a method of fabricating the array substrate 100 described with reference to FIG. 3.

In a method of fabricating the array substrate according to the present exemplary embodiment, a gate metal, for example, aluminum (Al) or molybdenum (Mo), is first deposited on the first base substrate 110 formed of a glass material with a predetermined thickness, for example, about 1,000 to 3,000 Å, by sputtering or the like. The gate lines GL, the gate electrode protruding from the gate line GL, and voltage application lines 120 are formed by an etching process as illustrated in FIG. 4A. The gate lines GL are extended in parallel approximately in the horizontal (x) direction on the first base substrate 110. A voltage application line Vcst may be formed together with the gate lines GL and the gate electrode while being spaced apart from the gate lines GL on the same layer. The voltage application lines 120

The voltage application lines 120 may comprise two lines disposed between the gate lines GL adjacent to each other and parallel to the gate lines GL, and two lines connected to the two lines disposed between the gate lines GL adjacent to each other.

Then, as illustrated in FIG. 4B, the gate insulating layer 130, a semiconductor layer and the active pattern 140 are formed. The gate insulating layer 130 is formed of an insulating material, for example, a silicon nitride (SiNx), with a predetermined thickness, for example, about 3,000 to 5,000 Å, on the gate line 120. A material for a semiconductor, for example, an amorphous silicon (a-Si) layer or an amorphous silicon (n+ a-Si) layer, which is n+ doped with high concentration, is deposited on the gate insulating layer 130 with a predetermined thickness, for example, about 200 to 500 Å, and etched to form the semiconductor layer and the active pattern 140. The semiconductor layer is formed on the gate insulating layer 130 on the gate line 120.

Subsequently, as illustrated in FIG. 4G, a data metal, for example, copper, aluminum, and molybdenum, is deposited on the semiconductor layer and the active pattern 140 with a predetermined thickness and patterned to form the data line 150, the source electrode, and the drain electrode.

The voltage application line 120 and the data line 150 are to be formed to at least partially overlap each other. As long as the overlapping can block light emitted from the lower backlight, a degree of the overlapping is not limited. Through the application of the aforementioned structure, it is possible to prevent light leakage by fundamentally blocking light emitted from the lower backlight.

This may be compared with FIG. 2 illustrating the SPVA structure in the related art. For the SPVA structure in the related art, light emitted from the backlight leaks through a space between the voltage application lines 12 and the data line 15. However, when the voltage application line 120 and the data line 150 according to the inventive concept overlaps, it is possible to block light from the backlight from leaking.

When a layer formed of semiconductor material and the data metal layer are etched together by a single etching process, the semiconductor layer is foamed under the source and the drain electrode and on the gate insulating layer 130 on the gate line 120, and the active pattern 140 is formed under the data line 150 and on the gate insulating layer 130, and the semiconductor layer between the source electrode and the drain electrode is formed as a channel layer through an etch back process.

The gate electrode, the gate insulating layer 130, the semiconductor layer, and the source and drain electrodes configure a switching element TR that is a three-terminal element.

Then, as illustrated in FIG. 4D, the organic layer 160 for covering the first base substrate 110, on which the data line 150, the source and drain electrodes are formed, is formed. The organic layer 160 may be formed of an organic transparent material with a predetermined thickness. The organic layer 160 decreases parasitic capacitance between the pixel electrode 180, which is to be described below, and the data line 150.

Next, as illustrated in FIG. 4E, the shielding electrode 170 and the pixel electrode 180 are formed on the organic layer 160. The shielding electrode 170 blocks parasitic capacitance from being formed between the data line 150, the voltage application lines 120, and the pixel electrode 180. On the other hand, the voltage application lines 120 forms a storage capacitor with the pixel electrode 180 to maintain a pixel voltage applied to the pixel electrode 180 for one frame.

The shielding electrode 170 and the pixel electrode 180 may be formed by depositing a transparent conductive material, such as an indium tin oxide (ITO) or an indium zinc oxide (IZO), on the organic layer 160 with a thickness, for example, about 800 to 1,200 Å, and patterning the transparent conductive material.

When the structure, in which the voltage application lines 120 and the data line 150 overlap each other, is applied, a width of the shielding electrode 170 may be decreased compared to that in the related art, so that a width of the pixel electrode 180 may be increased, and thus a non-transmissive part is decreased compared to that in the related art, thereby being advantageous in transmissivity. For example, a width of the shielding electrode 170 positioned on the data line 150 and the gate line 120 is smaller than a width of the data line 150.

Referring back to FIG. 3, the opposite substrate 200 may include a second base substrate 210, a color filter pattern 220, an over coating layer 230, and the common electrode 240.

A black matrix is generally formed on a lower surface of the second base substrate 210 so as to correspond to the gate lines GL, the voltage application lines 120, the data lines 150, and the switching element TR. However, in accordance with this embodiment, when the structure, in which the voltage application lines 120 and the data lines 150 overlap each other, is applied, the black matrix is not necessary.

Accordingly, the color filter pattern 220 is formed on the second base substrate 210 corresponding to the pixel area. The color filter pattern 220 may include, for example, a red filter, a green filter, and a blue filter. The color filters may be disposed on the pixel areas PA, respectively, in the horizontal direction in an order of the red filter, the green filter, and the blue filter.

The over coating layer 230 covers the color filter pattern 220, and the common electrode 240 is formed on the over coating layer 230.

Next, the liquid crystal layer 300 may be vertically aligned by additionally forming an upper alignment layer on the common electrode 240.

The liquid crystal display is fabricated by a process of boding the array substrate fabricated as described above and the opposite substrate.

In the exemplary embodiment, the liquid crystal display having the SPVA structure has been described, but the structure, in which the gate line 120 and the data line 150 overlap each other, may also be applied to the SVA structure.

Referring to FIG. 5, a liquid crystal display according to another exemplary embodiment includes an array substrate 100, an opposite substrate 200, and a liquid crystal layer 300. The array substrate 100 includes a first base substrate 110, gate lines GL, voltage application lines 120, data lines 150, a switching element TR, a color filter pattern 220, a shielding electrode 170, and a pixel electrode 180. The opposite substrate 200 includes a second base substrate 210, an over coating layer 230, and a common electrode 240.

In the array substrate 100, a gate metal is deposited on the first base substrate 110 formed of a glass material by sputtering and the like, and the gate lines GL and a gate electrode protruding from the gate line GL are formed by an etching process. Similarly, voltage application lines 120 are formed together with the gate lines GL while being spaced apart from the gate lines GL on the same layer.

Then, a gate insulating layer 130 and an active pattern 140 are formed. The gate insulating layer 130 is formed on the gate lines GL, the gate electrode and the voltage application line 120. The active pattern 140 is formed by depositing a layer formed of semiconductor material on the gate insulating layer 130 and etching the layer.

Subsequently, the data line 150 and source and drain electrodes are formed by depositing a data metal on the gate insulating layer 130 and patterning the data metal.

Here, the voltage application lines 120 and the data lines 150 are formed to have widths greater than those in the related art, so that the voltage application lines 120 and the data lines 150 are to be formed to partially overlap each other. Through the application of the aforementioned structure, light emitted from the lower backlight is fundamentally blocked to prevent light leakage. In this case, the voltage application lines 120 may be formed to have a width greater than that of the related art, but the data lines 150 may also be formed to have a width greater than that of the related art.

When the layer form of semiconductor material and the data metal layer are etched together by a single etching process, the semiconductor layer is formed under the source and the drain electrode and on the gate insulating layer 130 on the gate line 120, and the active pattern 140 is formed under the data line 150 and on the gate insulating layer 130, and the semiconductor layer between the source electrode and the drain electrode is formed as a channel layer through an etch back process.

The gate electrode, the gate insulating layer 130, the semiconductor layer, and the source and drain electrodes configure a switching element TR that is a three-terminal element.

The color filter pattern 220 is formed on the first base substrate 110 on which the data line 150 is formed. The color filter pattern 220 may include, for example, a red filter, a green filter, and a blue filter. The color filters may be disposed on the pixel areas PA, respectively, in the horizontal direction in an order of the red filter, the green filter, and the blue filter.

The shielding electrode 170 and the pixel electrode 180 are formed on the color filter pattern 220. The shielding electrode 170 blocks parasitic capacitance from being formed between the data line 150, the voltage application line 120, and the pixel electrode 180. On the other hand, the voltage application lines 120 form a storage capacitor with the pixel electrode 180 to maintain a pixel voltage applied to the pixel electrode 180 for one frame.

The shielding electrode 170 and the pixel electrode may be formed by depositing a transparent conductive material on the color filter pattern 220 and pattering the transparent conductive material.

When the structure, in which the voltage application lines 120 and the data lines 150 overlap each other, is applied, the shielding electrode 170 width may be decreased, so that the pixel electrode 180 may be increased, and thus a non-transmissive part is decreased compared to that in the related art, thereby being advantageous in transmissivity.

The opposite substrate 200 may include a second base substrate 210, an over coating layer 230, and a common electrode 240.

Accordingly, the over coating layer 230 is formed on the second base substrate corresponding to the pixel area PA, and subsequently, the common electrode 240 is formed on the over coating layer 230.

Next, the liquid crystal layer 300 may be vertically aligned by forming an upper alignment layer on the common electrode 240.

The liquid crystal display is fabricated by a process of boding the array substrate fabricated as described above and the opposite substrate.

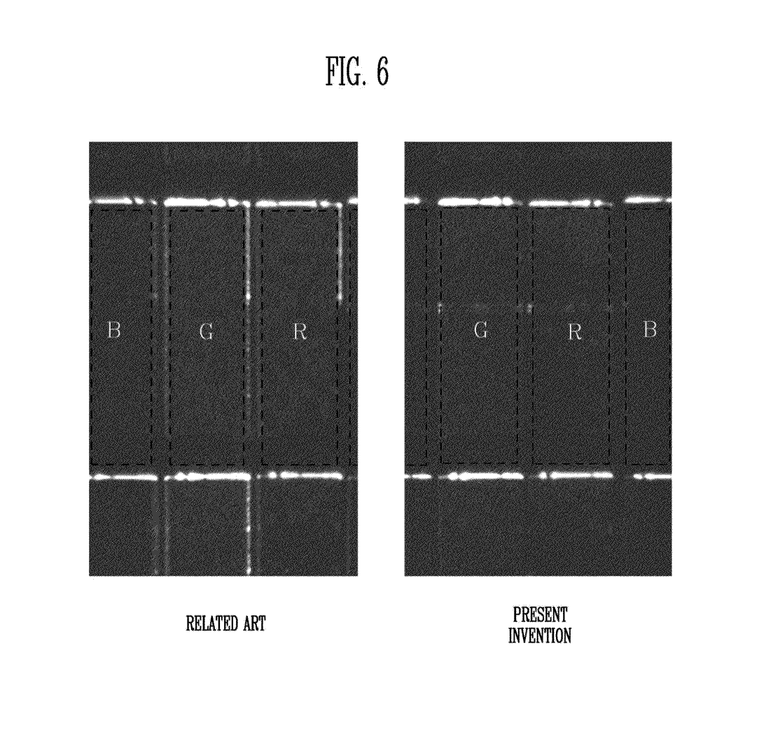

FIG. 6 is a picture of a comparison of leakage of black light between the liquid crystal display having the SPVA structure in the related art illustrated in FIG. 2 (left in the view of FIG. 6), and the liquid crystal display according to the exemplary embodiment illustrated in FIG. 3 (right in the view FIG. 6). Here, in order to intensify generation of the light leakage, light leakage in black was confirmed by increasing a voltage of the voltage application lines to 12 V. According to the picture, it can be seen that light leakage of the liquid crystal display according to the exemplary embodiment is decreased.

In the meantime, it is described that the inventive concept is applied to the liquid crystal display including the SPVA structure and the SVA structure, but the inventive concept is not limited thereto, and is applicable to liquid crystal displays having all of the various pixel structures, such as a PVA. Further, the inventive concept is usable in all of the driving methods, such as CS/RD/TT, and the like.

The inventive concept may have various modifications and exemplary embodiments and thus specific exemplary embodiments will be illustrated in the drawings and described. However, it is not intended to limit the inventive concept to the specific exemplary embodiments, and it will be appreciated that the inventive concept includes all modifications, equivalences, or substitutions included in the spirit and the technical scope of the inventive concept.

In the description of respective drawings, similar reference numerals designate similar elements. In the accompanying drawings, sizes of structures are illustrated to be enlarged compared to actual sizes for clarity.

Terms “first”, “second”, and the like may be used for describing various constituent elements, but the constituent elements should not be limited to the terms. The terms are used only to discriminate one constituent element from another constituent element. For example, a first element could be termed a second element, and similarly, a second element could be also termed a first element without departing from the scope of the present disclosure. Singular expressions used herein include plurals expressions unless they have definitely opposite meanings.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other specific characteristics, numbers, steps, operations, constituent elements, and components, or a combination thereof in advance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the inventive concept as set forth in the following claims.

What is claimed is:

1. A liquid crystal display comprising:
an array substrate;
an opposite substrate facing to the array substrate; and
a liquid crystal layer between the array substrate and the opposite substrate,
wherein the array substrate includes a first base substrate in which pixel areas are defined, and the first base substrate includes a gate line, a data line crossing the gate line, voltage application lines having two lines disposed at both sides of the data line and parallel to the data line, a switching element connected with the gate line and the data line in the pixel area, and a shielding electrode and a pixel electrode on the data line, and
wherein the data line and the two lines disposed at both sides of the data line at least partially overlap.

2. The liquid crystal display of claim 1, wherein a width of the shielding electrode positioned on the data line and the voltage application lines is smaller than a width of the data line according to overlapping of the data line and the voltage application lines.

3. The liquid crystal display of claim 1, further comprising:
a gate insulating layer between the gate line and the data line.

4. The liquid crystal display of claim 1, further comprising:
an organic layer between the data line and the shielding electrode.

5. The liquid crystal display of claim 1, wherein the opposite substrate does not include a vertical black matrix in an area of the data line.

6. The liquid crystal display of claim 1, wherein the liquid crystal display has a Super Patterned Vertical Alignment (SPVA) structure.

7. The liquid crystal display of claim 1, wherein the liquid crystal display has a Super Vertical Alignment (SVA) structure.

8. A method of fabricating a liquid crystal display, comprising:
forming an array substrate including a first base substrate and a plurality of pixels included on the first base substrate;
forming an opposite substrate including a common electrode provided on a second base substrate; and
forming a liquid crystal layer between the array substrate and the opposite substrate,
wherein the forming of the array substrate includes forming a gate line and voltage application lines, forming a data line crossing the gate line on the first base substrate, forming a switching element connected with the gate line and the data line in a pixel area, and forming a shielding electrode and a pixel electrode on the data line,
wherein the voltage application lines have two lines disposed at both sides of the data line and parallel to the data line, and
wherein the data line and the two lines disposed at both sides of the data line at least partially overlap.

9. The method of claim 8, wherein a width of the shielding electrode positioned on the data line and the voltage application lines is smaller than a width of the data line according to overlapping of the data line and the voltage application line.

10. The method of claim 8, wherein the opposite substrate does not include a vertical black matrix in an area of the data line.
